(19) United States
(12) Patent Application Publication
(10) Pub. No.: US 2025/0203812 A1
(43) Pub. Date: Jun. 19, 2025

(54) LEAKAGE GATHERING ASSEMBLY AND ELECTRONIC APPARATUS

(71) Applicant: Wiwynn Corporation, New Taipei City (TW)

(72) Inventors: Hung Chien Wu, New Taipei City (TW); PO HAN HUANG, New Taipei City (TW); Zi-Ping Wu, New Taipei City (TW); Tai-Ying Tu, New Taipei City (TW)

(21) Appl. No.: 18/780,587

(22) Filed: Jul. 23, 2024

(30) Foreign Application Priority Data
Dec. 14, 2023 (TW) 112148754

(51) Int. Cl. H05K 7/20

(52) U.S. Cl. CPC H05K 7/20272; H05K 7/20781

(57) ABSTRACT

A leakage gathering assembly includes a leakage gathering tray. The leakage gathering tray has a surface, a plurality of conveying channels, a convergent channel and a plurality of identification recesses. The conveying channels, the convergent channel and the identification recesses are recessed from the surface, the conveying channels communicate with the convergent channel, the identification recesses respectively communicate with the conveying channels, and depths of the identification recesses are greater than depths of the conveying channels.

### CROSS-REFERENCE TO RELATED APPLICATIONS

This non-provisional application claims priority under 35 U.S.C. § 119 (a) on Patent Application No(s). 112148754 filed in Taiwan, R.O.C. on Dec. 14, 2023, the entire contents of which are hereby incorporated by reference.

### TECHNICAL FIELD

The disclosure relates to a leakage gathering assembly and an electronic apparatus.

### BACKGROUND

At present, more electronic apparatuses (e.g., servers) use liquid cooling manner to dissipate heat generated by expansion cards therein. Each expansion card is provided with joints, and there is a leakage detector provided near each joint, such that which joint leakage occurs at can be identified from a signal transmitted by the corresponding leakage detector. The quantity of the leakage detectors corresponds to the quantity of the joints, and thus the leakage detectors occupies a large space and increase costs and complexity of wire arrangement.

Moreover, a maintainer requires to power off the electronic apparatus before maintaining the joints. However, the powered-off electronic apparatus is unable to provide leakage information anymore, and thus the maintainer requires to remember the leak information before the electronic apparatus is powered off, which may easily cause misjudgments and oversights, and has low maintenance efficiency. Accordingly, how to solve the aforementioned issues are crucial topics in this field.

### SUMMARY

The disclosure provides a leakage gathering assembly and an electronic apparatus which are capable of preventing misjudgments and oversights of the maintainer.

One embodiment of the disclosure provides a leakage gathering assembly. The leakage gathering assembly includes a leakage gathering tray. The leakage gathering tray has a surface, a plurality of conveying channels, a convergent channel and a plurality of identification recesses. The conveying channels, the convergent channel and the identification recesses are recessed from the surface, the conveying channels communicate with the convergent channel, the identification recesses respectively communicate with the conveying channels, and depths of the identification recesses are greater than depths of the conveying channels.

Another embodiment of the disclosure provides an electronic apparatus. The electronic apparatus includes a casing, a plurality of expansion cards, a manifold, a plurality of joints and a leakage gathering assembly. The expansion cards are located in the casing. The manifold is located in the casing. The manifold and the expansion cards are connected to each other via the joints. The leakage gathering assembly is located in the casing and includes a leakage gathering tray. The leakage gathering tray has a surface, a plurality of conveying channels, a convergent channel and a plurality of identification recesses. The conveying channels, the convergent channel and the identification recesses are recessed from the surface, the conveying channels communicate with the convergent channel, the identification recesses respectively correspond to the joints and respectively communicate with the conveying channels, and depths of the identification recesses are greater than depths of the conveying channels.

According to the leakage gathering assembly and the electronic apparatus as discussed in the above embodiments, the identification recesses respectively correspond to the joints and respectively communicate with the conveying channels, and the depths of the identification recesses are greater than the depths of the conveying channels. Therefore, when a leakage occurs at any two of the joints assembled with each other, a part of leaking coolant can be retained in the corresponding identification recess. As a result, after the electronic apparatus is powered off, and its cover is removed, the maintainer can quickly and accurately identify at which two of the joints the leakage occurs from the corresponding identification recess retaining the coolant, thereby preventing misjudgments and oversights of the maintainer.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of an electronic apparatus according to one embodiment of the disclosure;

FIG. 2 is a partial cross-sectional view of the electronic apparatus in FIG. 1;

FIG. 3 is a partial perspective view of a leakage gathering assembly in FIG. 1;

FIG. 4 is a partial and enlarged perspective view of the leakage gathering assembly in FIG. 1; and

FIG. 5 is a partial perspective view of a leakage gathering assembly according to another embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

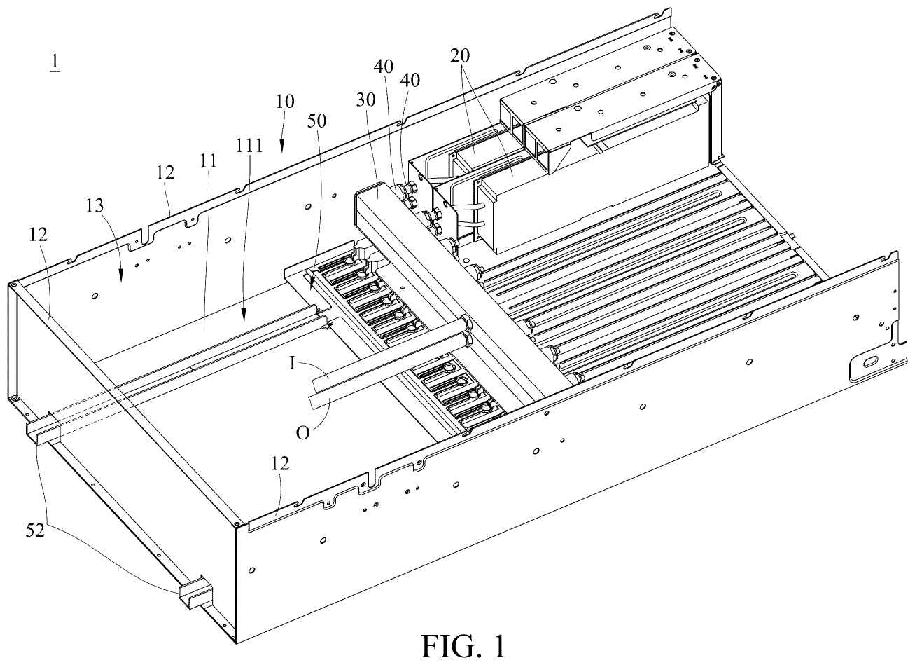

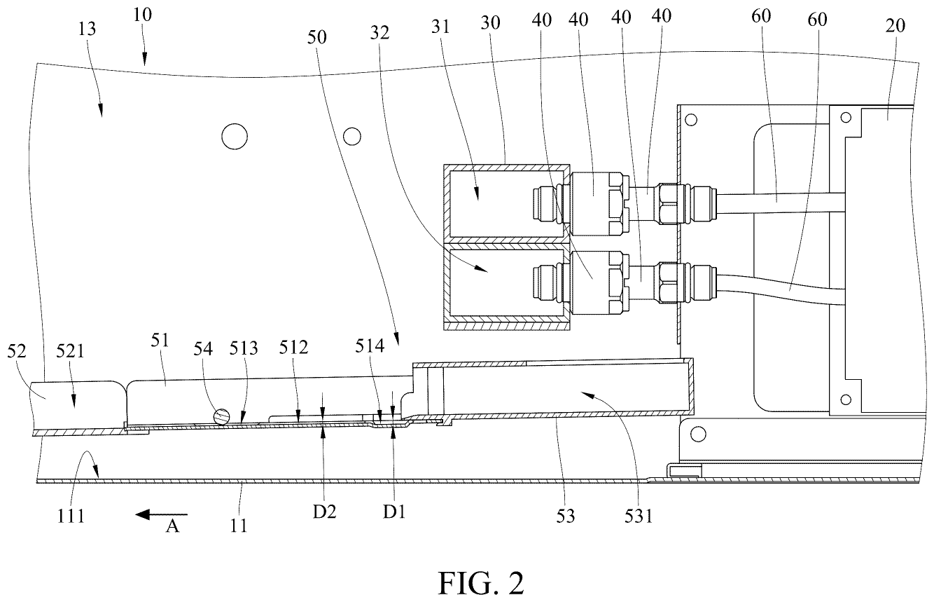

Referring to FIGS. 1 and 2, FIG. 1 is a perspective view of an electronic apparatus 1 according to one embodiment of the disclosure, and FIG. 2 is a partial cross-sectional view of the electronic apparatus 1 in FIG. 1.

In this embodiment, the electronic apparatus 1 is, for example, a server. The electronic apparatus 1 includes a casing 10, a plurality of expansion cards 20, a manifold 30, a plurality of joints 40 and a leakage gathering assembly 50. In addition, the electronic apparatus 1 may further include a plurality of connection pipes 60.

The casing 10, for example, includes a bottom plate 11 and a plurality of side walls 12. The bottom plate 11 has a support surface 111. The side walls 12 stand on different sides of the support surface 111 of the bottom plate 11, and the bottom plate 11 and the side walls 12 together form an accommodation space 13. The expansion cards 20, the manifold 30 and the leakage gathering assembly 50 are located in the accommodation space 13 of the casing 10, and the support surface 111 of the bottom plate 11 faces the expansion cards 20, the manifold 30 and the leakage gathering assembly 50. In addition, the casing 10 may further include a cover (not shown), and the cover is located opposite to the bottom plate 11 and covers the accommodation space 13. However, in order to clearly show connections among the expansion cards 20, the manifold 30, the joints 40 and the leakage gathering assembly 50, the cover is omitted in the figures.

Coolant may flow into the expansion cards 20 from the manifold 30 for cooling the expansion card 20, where the expansion cards are, for example, graphics cards. The manifold 30 has a first chamber 31 and a second chamber 32 separated from each other. One side of the first chamber 31 and one side of the second chamber 32 of the manifold 30 are respectively connected to an inlet pipe I and an outlet pipe O, and another side of the first chamber 31 and another side of the second chamber 32 of the manifold 30 communicate with the expansion cards 20 via the joints 40 and the connection pipes 60.

Note that the connection pipes 60 are optional components. In some other embodiments, the electronic apparatus may not include the connection pipes, and the first chamber and the second chamber of the manifold may communicate with the expansion cards via the joints merely.

In this embodiment, the manifold 30, the expansion card 20, a pump (not shown) and a heat exchanger (not shown) may form a liquid cooling loop for coolant to flow therein. The pump can drive the coolant to flow into the first chamber 31 of the manifold 30 via the inlet pipe I, and then flow into the expansion cards 20 via a part of the joints 40 and a part of the connection pipes 60 for absorbing heat generated by the expansion cards 20. Then, the hot coolant after absorbing heat generated by the expansion cards 20 may flow into the second chamber 32 of the manifold 30 via another part of the connection pipes 60 and another part of the joints 40, and then flow into the heat exchanger via the outlet pipe O for being cooled. As a result, during the operation of the pump, the coolant can cyclically flow in the liquid cooling loop to dissipate heat generated by the expansion cards 20, such that the expansion cards 20 can operate in an appropriate temperature.

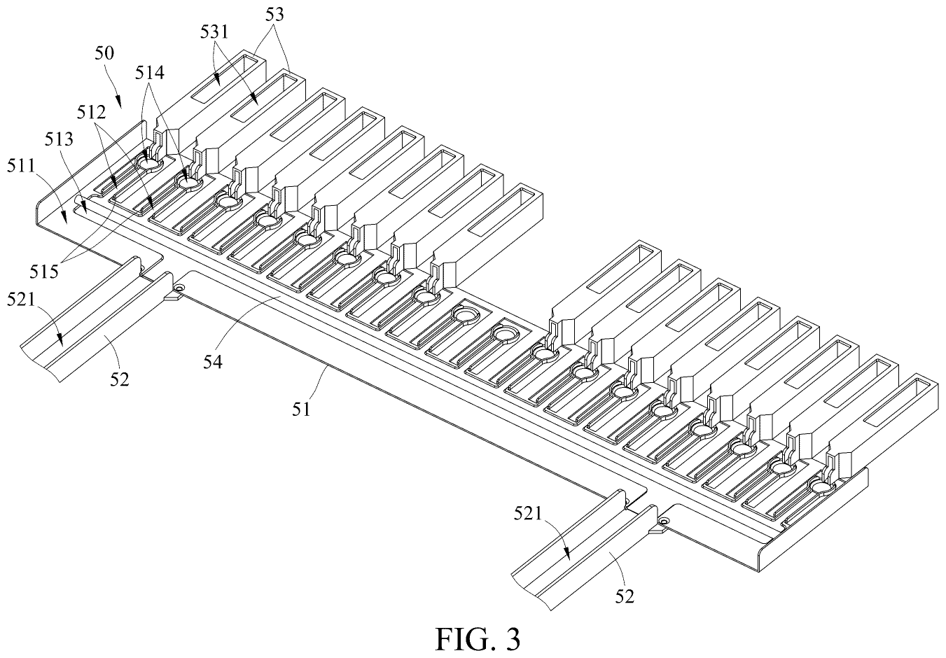

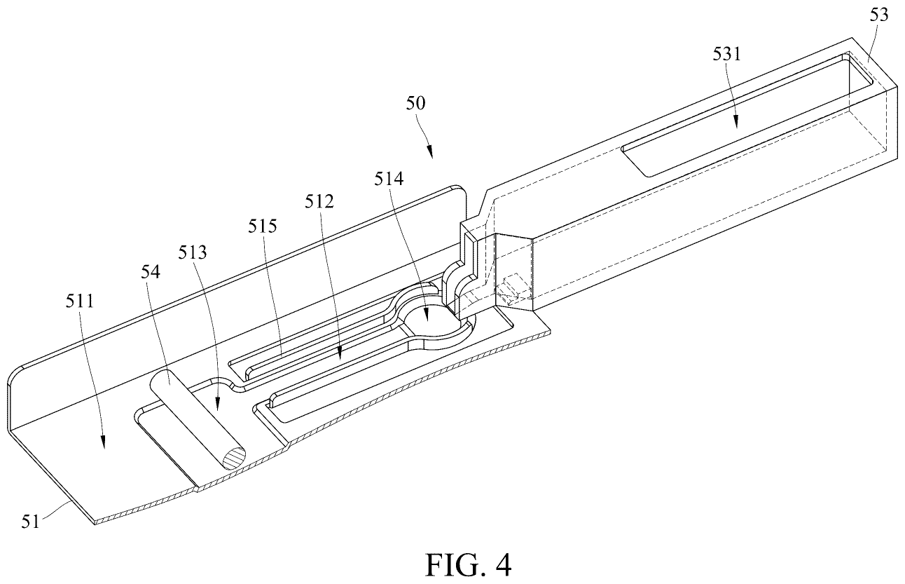

Then, referring to FIGS. 2 to 4, FIG. 3 is a partial perspective view of a leakage gathering assembly 50 in FIG. 1, and FIG. 4 is a partial and enlarged perspective view of the leakage gathering assembly 50 in FIG. 1.

The leakage gathering assembly 50 includes a leakage gathering tray 51. The leakage gathering tray 51 has a surface 511, a plurality of conveying channels 512, a convergent channel 513, a plurality of identification recesses 514 and a plurality of partition portions 515. The conveying channels 512, the convergent channel 513 and the identification recesses 514 are recessed from the surface 511. The conveying channels 512 communicate with the convergent channel 513 in parallel, and the identification recesses 514 respectively communicate with the conveying channels 512. Specifically, the identification recesses 514 are respectively located at sides of the conveying channels 512 located farther away from the convergent channel 513. In other words, the conveying channels 512 are located between the identification recesses 514 and the convergent channel 513. Depths D1 of the identification recesses 514 relative to the surface 511 are, for example, greater than depths D2 of the conveying channels 512 relative to the surface 511. For example, the partition portions 515 are formed by bending a sheet to protrude from the surface 511, but not limited thereto. The partition portions 515 are located between every adjacent two of the conveying channels 512 and between every adjacent two of the identification recesses 514; that is, each of the partition portions 515 extend aside one conveying channel 512 and one identification recess 514 which communicate with each other.

In this embodiment, the leakage gathering assembly 50 may further include two discharging components 52. The discharging components 52 are mounted on the leakage gathering tray 51, and each of the discharging components 52 has a discharging channel 521. For example, the discharging channels 521 of the discharging components 52 communicate with one side of the convergent channel 513 located farther away from the conveying channels 512. The discharging components 52 extend in the accommodation space 13 of the casing 10 and is penetrated through one of side walls 12 of the casing 10 (e.g., shown in FIG. 1).

In this embodiment, the leakage gathering assembly 50 may further include a plurality of leakage receiving components 53. The leakage receiving components 53 are disposed on the leakage gathering tray 51, and each of the leakage receiving components 53 has a guide channel 531. The guide channels 531 respectively communicate with the identification recesses 514, such that the guide channels 531 respectively communicate with the conveying channels 512 via the identification recesses 514.

Note that the leakage receiving components 53 and the discharging components 52 are not limited to being connected to the leakage gathering tray 51 via an installation manner. In some other embodiments, the leakage receiving components and the discharging components may be integrally connected to the leakage gathering tray.

In this embodiment, distances from the guide channels 531, the conveying channels 512, the convergent channel 513 and the discharging channels 521 to the support surface 111 gradually decreases along a direction A (e.g., shown in FIG. 2). In other words, the guide channels 531, the conveying channels 512, the convergent channel 513 and the discharging channels 521 are inclined channels or passages formed with discharge slopes. Furthermore, the guide channel 531 of each of the leakage receiving components 53 corresponds to two of the joints 40 assembled with each other. For example, the guide channel 531 of each of the leakage receiving components 53 are located below two of the joints 40 assembled with each other. As a result, when a leakage occurs in these two of the joints 40 (e.g., male and female joints) assembled with each other, the guide channel 531 of the corresponding leakage receiving component 53 can receive the coolant leaking therefrom.

In this embodiment, the leakage gathering assembly 50 may further include a leakage detector 54. The leakage detector 54 is, for example, a leakage detecting rope. The leakage detector 54 is disposed in the convergent channel 513, and is, for example, in signal communication with a control circuit board (not shown) of the electronic apparatus 1. This control circuit board is, for example, in signal communication with a warning lamp (not shown) and/or an external monitoring system, such that a maintainer can identify that a leakage occurs at the joints 40 in the electronic apparatus 1 from a variation of the warning lamp and/or a signal from the control circuit board.

After the guide channel 531 of the leakage receiving component 53 receives the leaking coolant, the slope of the guide channel 531 forces the coolant to flow towards the identification recess 514 and accumulates in the identification recess 514. During the accumulation of the coolant in the identification recess 514, once the liquid level of the coolant exceeds the bottom of the conveying channel 512, the coolant flows to the convergent channel 513 through the conveying channel 512. Then, the coolant discharges out of the casing 10 through the discharging channels 521 of the discharging components 52.

When the coolant flows to the convergent channel 513 as mentioned above, the coolant wets the leakage detector 54, such that the leakage detector 54 have a resistance variation and transmits a signal to the control circuit board of the electronic apparatus 1, and thus the control circuit board lights up the warning lamp and/or transmits a signal to the external monitoring system. As a result, the maintainer can identify that a leakage occurs at the joints 40 in the electronic apparatus 1 from the warning lamp and/or a notice provided by the external monitoring system, and thus requires to power off the electronic apparatus 1 and removes the cover of the electronic apparatus 1 to perform maintenance.

In this embodiment, the identification recesses 514 correspond to the joints 40 via the guide channels 531, respectively, and the depths D1 of the identification recesses 514 are greater than the depths D2 of the conveying channels 512. Therefore, when a leakage occurs at any two of the joints 40 assembled with each other, a part of leaking coolant can be retained in the corresponding identification recess 514. As a result, after the electronic apparatus 1 is powered off, and its cover is removed, the maintainer can quickly and accurately identify at which two of the joints 40 the leakage occurs from the corresponding identification recess 514 retaining the coolant, thereby preventing misjudgments and oversights of the maintainer.

In this embodiment, the identification recesses 514, the conveying channels 512 and the convergent channel 513 are all recessed from the surface 511 which is flat, but the disclosure is not limited thereto. In some other embodiments, the identification recesses, the conveying channels and the convergent channel may be recessed from different surfaces of different heights as along as the depths of the identification recesses are greater than the depths of portions of the conveying channels connected to the identification recesses (or bottom surfaces of identification recesses are lower than bottom surfaces of the portions of the conveying channels connected to the identification recesses) for retaining the leaking coolant in the identification recesses.

In this embodiment, the identification recesses 514 of the leakage gathering tray 51 have the effect of identifying at which two of the joints 40 the leakage occurs, and thus the quantity of the leakage detector 54 arranged on the leakage gathering tray 51 for informing the maintainer that a leakage occurs can be fewer than the quantity of the joints 40. Therefore, arranging the leakage detectors with the same quantity as the joints 40 for determining at which two of the joints 40 the leakage occurs is not required. As a result, the quantity of the leakage detector 54 and the quantity of connectors on the control circuit board to be assembled with the leakage detector 54 can be saved, thereby reducing space occupied by the leakage detectors and the connectors, reducing costs and facilitating wire arrangement and maintenance. In this embodiment, since there is only one leakage detector 54 provided on the leakage gathering tray 51, and thus aforementioned effects can be further enhanced.

In this embodiment, the guide channels 531, the conveying channels 512, the convergent channel 513 and the discharging channels 521 are inclined channels or passages, such that the coolant leaking from two of the joints 40 assembled with each other can flow out of the casing 10 via gravity. However, the guide channels 531, the conveying channels 512, the convergent channel 513 and the discharging channels 521 are not limited to being all inclined channels or passages. In some other embodiments, only some of the guide channels, the conveying channels, the convergent channel, and the discharging channels, are inclined channels or passages; alternatively, all of them may be horizontal channels or passages. In such a case, capillary structures may be provided in the channels or passages mentioned above for facilitating the flowing of the coolant.

In this embodiment, the partition portions 515 ensure that the coolant in the identification recesses 514 and the conveying channels 512 does not flow on the surface 511 of the leakage gathering tray 51, and thus the coolant can converge in the convergent channel 513 in a predetermined path and then flow out of the casing 10 via the discharging channels 521 of the discharging components 52.

Note that the partition portions 515 are not limited to extending aside the conveying channels 512 and the identification recesses 514. In some other embodiments, the partition portions may be merely located aside the conveying channels or the identification recesses. In addition, the partition portions 515 are optional structures and may be omitted in some other embodiments.

In this embodiment, the leakage gathering tray 51, the leakage receiving components 53, the discharging components 52 and the leakage detector 54 of the leakage gathering assembly 50 are modularized, facilitating installation and removal of the leakage gathering assembly 50.

Note that the leakage detector 54 is an optional component. In some other embodiments, the leakage gathering assembly may not include the leakage detector. In such a case, whether the leakage occurs or not can be determined by whether the coolant flowing through the discharging components or not.

Moreover, the quantity of the discharging components 52 are not limited in the disclosure and may be modified to be one in some other embodiments. In another embodiment, the leakage gathering assembly may not include the discharging component, and the convergent channel of the leakage gathering tray may extend out of the casing.

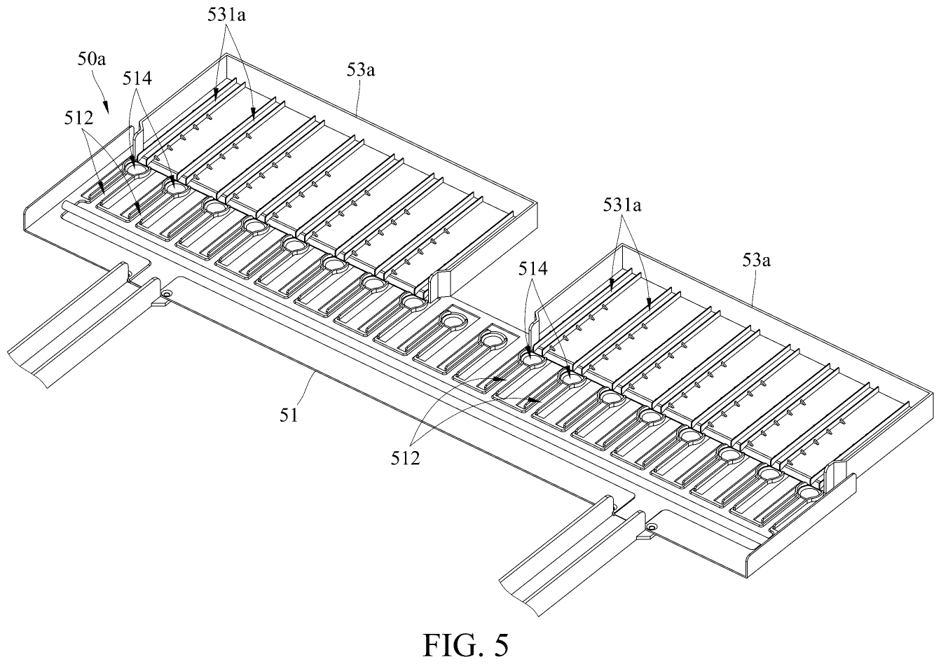

Then, referring to FIG. 5, FIG. 5 is a partial perspective view of a leakage gathering assembly 50a according to another embodiment of the disclosure.

The leakage gathering assembly 50a of this embodiment is similar to the leakage gathering assembly 50 of the previous embodiment, and the main difference between them is the structure of the leakage receiving components. Therefore, leakage receiving components 53a of the leakage gathering assembly 50a are mainly introduced in the following paragraphs, and the same part between the leakage gathering assembly 50a and the leakage gathering assembly 50 will not be repeatedly introduced hereinafter.

In this embodiment, the leakage gathering assembly 50a includes two leakage receiving components 53a. The two leakage receiving components 53a are connected to the same side of the leakage gathering tray 51. For example, the two leakage receiving components 53a may be connected to the same side of the leakage gathering tray 51 via an installation manner, or the two leakage receiving components 53a may be integrally connected to the same side of the leakage gathering tray 51. Each of the leakage receiving components 53a has a plurality of guide channels 531a. For example, each of the leakage receiving components 53a and the guide channels 531a thereof are formed in one piece. The guide channels 531a communicate with the conveying channels 512 via the identification recesses 514 of the leakage gathering tray 51, respectively.

Note that the quantity of the leakage receiving components 53a of the leakage gathering assembly 50a is not limited to two and may be modified to be one or more than two in some other embodiments.

Note that the leakage receiving component 53 and the leakage receiving component 53a of the aforementioned embodiments are optional components. In some other embodiments, the leakage gathering assembly may not include the leakage receiving components. In such a case, the identification recesses of the leakage gathering tray may directly correspond to the joints, respectively. Moreover, the identification recesses of the leakage gathering tray are not limited to being located at sides of the conveying channels located farther away from the convergent channel. In some other embodiments, the identification recesses of the leakage gathering tray may be located between opposite ends of the conveying channels, or the conveying channels may communicate with the convergent channel via the identification recesses.

In addition, in the aforementioned embodiments, the identification recesses 514 having deeper depths are used to retain the coolant leaking from the joints 40 for identifying at which of the joints 40 the leakage occurs. However, other means can be adopted to further facilitate the maintainer to identify at which of the joints 40 the leakage occurs. For example, dyes (not shown) may be added in the identification recesses 514 for identifying at which of the joints 40 the leakage occurs with the colors of the dyes, and the dyes may have the same color or different colors. Alternatively, indicator papers (not shown) may be provided in the identification recesses 514 for identifying at which of the joints 40 the leakage occurs with wetted indicator papers.

According to the leakage gathering assemblies and the electronic apparatus as discussed in the above embodiments, the identification recesses correspond to the joints via the guide channels, respectively, and the depths of the identification recesses are greater than the depths of the conveying channels. Therefore, when a leakage occurs at any two of the joints assembled with each other, a part of leaking coolant can be retained in the corresponding identification recess. As a result, after the electronic apparatus is powered off, and its cover is removed, the maintainer can quickly and accurately identify at which two of the joints the leakage occurs from the corresponding identification recess retaining the coolant, thereby preventing misjudgments and oversights of the maintainer.

In addition, the identification recesses of the leakage gathering tray can provide the effect of identifying at which two of the joints leakage occurs, and thus the quantity of the leakage detector arranged on the leakage gathering tray for informing the maintainer that a leakage occurs can be fewer than the joints. Therefore, arranging the leakage detectors with the same quantity as the joints for determining at which two of the joints the leakage occurs is not required. As a result, the quantity of the leakage detector and the quantity of connectors on the control circuit board to be assembled with the leakage detector can be saved, thereby reducing space occupied by the leakage detectors and the connectors, reducing costs and facilitating wire arrangement and maintenance.

Moreover, the guide channels, the conveying channels, the convergent channel, and the discharging channels are inclined channels or passages, such that the coolant leaking from two of the joints assembled with each other can flow out of the casing via gravity.

Furthermore, the partition portions ensure that the coolant in the identification recesses and the conveying channels does not flow on the surface of the leakage gathering tray, and thus the coolant can converge in the convergent channel in a predetermined path and then flow out of the casing via the discharging channels of the discharging components.

On the other hand, the leakage gathering tray, the leakage receiving components, the discharging components and the leakage detector of the leakage gathering assembly are modularized, facilitating installation and removal of the leakage gathering assembly.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A leakage gathering assembly, comprising:
a leakage gathering tray, having a surface, a plurality of conveying channels, a convergent channel and a plurality of identification recesses, wherein the plurality of conveying channels, the convergent channel and the plurality of identification recesses are recessed from the surface, the plurality of conveying channels communicate with the convergent channel, the plurality of identification recesses respectively communicate with the plurality of conveying channels, and depths of the plurality of identification recesses are greater than depths of the plurality of conveying channels.

2. The leakage gathering assembly according to claim 1, further comprising a plurality of leakage receiving components, wherein the plurality of leakage receiving components are disposed on the leakage gathering tray, each of the plurality of leakage receiving components has a guide channel, the guide channels of the plurality of leakage receiving components respectively communicate with the plurality of identification recesses.

3. The leakage gathering assembly according to claim 2, wherein the plurality of identification recesses are respectively located at sides of the plurality of conveying channels located farther away from the convergent channel, and the guide channels of the leakage receiving components respectively communicate with the plurality of the conveying channels via the plurality of identification recesses.

4. The leakage gathering assembly according to claim 1, further comprising at least one leakage receiving component, wherein the at least one leakage receiving component is disposed on the leakage gathering tray, the at least one leakage receiving component has a plurality of guide channels, and the plurality of guide channels respectively communicate with the plurality of identification recesses.

5. The leakage gathering assembly according to claim 4, wherein the plurality of identification recesses are respectively located at sides of the plurality of conveying channels located farther away from the convergent channel, and the plurality of guide channels of the at least one leakage receiving component respectively communicate with the plurality of conveying channels via the plurality of identification recesses.

6. The leakage gathering assembly according to claim 4, wherein the at least one leakage receiving component and the plurality of guide channels are formed in one piece.

7. The leakage gathering assembly according to claim 1, wherein the leakage gathering tray further has a plurality of partition portions, the plurality of partition portions protrudes from the surface, and the plurality of partition portions are respectively located between every adjacent two of the plurality of conveying channels or every adjacent two of the plurality of identification recesses.

8. The leakage gathering assembly according to claim 1, further comprising a leakage detector, wherein the leakage detector is disposed in the convergent channel.

9. The leakage gathering assembly according to claim 1, further comprising at least one discharging component, wherein the at least one discharging component has a discharging channel, the at least one discharging component is connected to the leakage gathering tray, and the discharging channel communicate with the convergent channel.

10. An electronic apparatus, comprising:
a casing;
a plurality of expansion cards, located in the casing;
a manifold, located in the casing;
a plurality of joints, wherein the manifold and the plurality of expansion cards are connected to each other via the plurality of joints; and
a leakage gathering assembly, located in the casing and comprising:
a leakage gathering tray, having a surface, a plurality of conveying channels, a convergent channel and a plurality of identification recesses, wherein the plurality of conveying channels, the convergent channel and the plurality of identification recesses are recessed from the surface, the plurality of conveying channels communicate with the convergent channel, the plurality of identification recesses respectively correspond to the plurality of joints and respectively communicate with the plurality of conveying channels, and depths of the plurality of identification recesses are greater than depths of the plurality of conveying channels.

11. The electronic apparatus according to claim 10, wherein the leakage gathering assembly further comprises a plurality of leakage receiving components, the plurality of leakage receiving components are disposed on the leakage gathering tray, each of the plurality of leakage receiving components has a guide channel, and the guide channels of the plurality of leakage receiving components respectively communicate with the plurality of identification recesses.

12. The electronic apparatus according to claim 11, wherein the plurality of identification recesses are respectively located at sides of the plurality of conveying channels located farther away from the convergent channel, and the guide channels of the leakage receiving components respectively communicate with the plurality of the conveying channels via the plurality of identification recesses.

13. The electronic apparatus according to claim 10, wherein the leakage gathering assembly further comprises at least one leakage receiving component, the at least one leakage receiving component is disposed on the leakage gathering tray, the at least one leakage receiving component has a plurality of guide channels, and the plurality of guide channels respectively communicate with the plurality of identification recesses.

14. The electronic apparatus according to claim 13, wherein the plurality of identification recesses are respectively located at sides of the plurality of conveying channels located farther away from the convergent channel, and the plurality of guide channels of the at least one leakage receiving component respectively communicate with the plurality of conveying channels via the plurality of identification recesses.

15. The electronic apparatus according to claim 13, wherein the at least one leakage receiving component and the plurality of guide channels are formed in one piece.

16. The electronic apparatus according to claim 10, wherein the leakage gathering tray further has a plurality of partition portions, the plurality of partition portions protrudes from the surface, and the plurality of partition portions are respectively located between every adjacent two of the plurality of conveying channels or every adjacent two of the plurality of identification recesses.

17. The electronic apparatus according to claim 10, wherein the leakage gathering assembly further comprises a leakage detector, and the leakage detector is disposed in the convergent channel.

18. The electronic apparatus according to claim 10, wherein the leakage gathering assembly further comprises at least one discharging component, the at least one discharging component has a discharging channel, the at least one discharging component is connected to the leakage gathering tray, and the discharging channel communicate with the convergent channel.

19. The electronic apparatus according to claim 18, wherein the casing has a support surface, the support surface faces the plurality of expansion cards, the manifold and the leakage gathering assembly, and distances from the plurality of conveying channels, the convergent channel and the discharging channel to the support surface gradually decrease along a direction.

20. The electronic apparatus according to claim 18, wherein the at least one discharging component extends in the casing and is penetrated through the casing.
